(19) United States
(12) Patent Application Publication
(10) Pub. No.: US 2010/0186810 A1
(43) Pub. Date: Jul. 29, 2010

(54) METHOD FOR THE FORMATION OF A NON-RECTIFYING BACK-CONTACT A CDTE/CDS THIN FILM SOLAR CELL

(76) Inventor: Nicola Romeo, Parma (IT)

Correspondence Address: POLLACK, P.C., THE CHRYSLER BUILDING, 132 EAST 43RD STREET, SUITE 760, NEW YORK, NY, 10017, US

(21) Appl. No.: 12/452,427

(22) PCT Filed: Jun. 28, 2007
(86) PCT No.: PCT/IT2007/000469

§ 371 Date: Mar. 26, 2010

(30) Foreign Application Priority Data
Feb. 8, 2005 (IT) LU2005A000002

(51) Int. Cl. H01L 31/0216; H01L 31/18; C23C 14/34; C25D 7/12

(52) U.S. Cl. 136/256; 438/98; 204/192.1; 205/157; 257/E31.119

(57) ABSTRACT

A method of forming a non-rectifying, ohmic contact on a p-type semiconductor CdTe thin film, which comprises the steps of depositing a layer of As₂Te₃ on a CdTe layer at a substrate temperature generally within a range of ambient temperature and 200° C.; depositing a layer of Cu on the As₂Te₃ layer; and bringing at least the deposited Cu layer to a temperature generally within a range of 150° C. and 250° C. The method is used to form a stable contact on CdTe/CdS thin film solar cells.

### FIELD OF THE INVENTION

The present invention relates to the field of the solar cells technology and more particularly concerns a process for the large-scale production of CdTe/CdS thin film solar cells. In particular, the invention relates to an improvement to this process relating to the formation of a non-rectifying back-contact. Even if in the present specification reference is made to “CdTe/CdS thin-film” solar cells for sake of simplicity, it is to be understood that this term includes all the salt mixtures comprised in the formula

ZnₓCd₁₋ₓS/CdTe_{y}S_{1-y}

wherein 0≦x≦0.2 and 0.9≦y≦1.

### BACKGROUND ART OF THE INVENTION

As is known, a typical configuration of a CdTe/CdS solar cell has a film sequence of the multi-layer arrangement comprising a transparent glass substrate carrying a transparent conductive oxide (TCO) film, a CdS film representing the n-semiconductor, a CdTe film representing the p-semiconductor and a metallic back-contact. A solar cell with a layer arrangement and structure of this type is disclosed, for example, in U.S. Pat. No. 5,304,499.

The commercial float glass may be used as a transparent substrate, but, in spite of its low cost, special glasses are often preferred to avoid drawbacks of the float glass, in particular Na diffusion into TCO film.

The most common TCO is In₂O₃ containing 10% of Sn (ITO). This material has a very low resistivity on the order of 3×10⁻⁴ Ωcm and high transparency (>85%) in the visible region of the solar spectrum. However, this material is made by sputtering and the ITO target after several runs forms some nodules which contain an In excess and a discharge between nodules can happen during sputtering which can damage the film. Another material which is commonly used is fluorine doped SnO2 which however exhibits a higher resistivity close to 10⁻³ Ωcm and as a consequence a 1 μm thick layer is needed in order for the sheet resistance to be around 10Ω/square. A high TCO thickness decreases the transparency and then the photocurrent of the solar cell. The use of Cd₂SnO₄ has also been proposed by the NREL group (X. Wu et al., Thin Solid Films, 286 (1996) 274-276). Also this material has some drawbacks since the target is made up of a mixture of CdO and SnO₂ and, being CdO highly hygroscopic, the stability of the target may result to be unsatisfactory.

WO03/032406, in the name of the same applicant, discloses a process for large-scale production of CdTe/CdS thin-film solar cells in which the deposition of the TCO film is conducted in such a way that a film of very low resistivity can be deposited without formation of any metal nodules on the target and allowing the use of a inexpensive substrate. To this end, the TCO layer is formed by sputtering in an inert gas atmosphere containing hydrogen, or an argon-hydrogen mixture, and a gaseous fluoralkyle compound, e.g. CHF₃. In this way the TCO is doped with fluorine.

The CdS film or layer is deposited by sputtering or Close-Spaced Sublimation (CSS) from CdS granulate material. This last technique allows the preparation of thin films at a substrate temperature much higher than that used in simple vacuum evaporation or sputtering, because substrate and evaporation source are put very close to each other at a distance of 2-6 mm and the deposition is carried out in the presence of an inert gas such as Ar, He or N₂ at a pressure of 10⁻¹-100 mbar. A higher substrate temperature allows the growth of a better crystalline quality material. An important characteristic of the close-spaced sublimation is a very high growth rate up to 10 μm/min, which is suitable for large-scale production.

CdTe film or layer is deposited on top of CdS film by close-spaced sublimation (CSS) at a substrate temperature of 480-520° C. CdTe granulate is generally used as a source of CdTe which is evaporated from an open crucible.

The electric back contact on the CdTe film is generally obtained by deposition of a film of a highly p-dopant metal for CdTe such as copper, e.g. in graphite contacts, which, upon annealing, can diffuse in the CdTe film. The use of a Sb₂Te₃ film as a back-contact in a CdTe/CdS solar cell has been disclosed by the same inventors (N. Romeo et al., A highly efficient and stable CdTe/CdS thin film solar cell, Solar Energy Materials & Solar Cells, 58 (1999), 209-218).

The back-contact in the CdTe/Cd thin film solar cells plays a very important role in achieving their efficiency. A rectifying contact, i.e. a metal-semiconductor contact which does not follow the Ohm law, that is to say there is no linear relationship between voltage and current, gives rise to a “roll over” (intersection in the first quadrant of the dark condition/lighting condition J-V characteristic curves) in the J-V characteristic, i.e. in the diagram showing the behaviour of the current density as a function of the voltage, which considerably decreases the “Fill factor”, and consequently the cell efficiency (D. Bonnet and P. V. Meyers, J. Mater. Res. 13 (1998) 2740-2753)). Since CdTe has an high electronic affinity (χ) and an high prohibited band (1.5 eV), the majority of the metals forms a Schottky barrier limiting the hole transport in the p-type CdTe. When using Cu to form the contact on the CdTe, before Cu deposition a chemical etching is carried out in a phosphoric/nitric acid bath (the so called N—P etching) on CdTe to create a Te-rich surface forming the CuₓTe (1≦X≦2) compound with Cu.

This compound, by interdiffusion, forms a low resistance close contact with CdTe, but its stability is limited to the CuₓTe phase in which 1≦X≦1.4, whereas the Cu₂Te phase is not a stable compound and therefore releases Cu which, being a fast diffusive element, penetrates the CdTe in particular through the grain edges, this possibly resulting in the cell degradation. Since Cu is a positive ion, its diffusion within CdTe depends on the internal electric field of the junction which, in turn, depends on the fact that the cell is undergone to an external bias or illumination. The device degradation is clearly faster when it is heated to a temperature higher than 60° C. or is subjected to high lighting (>1 sun).

In order to avoid or at least limit this drawback, the solar cells using this type of back-contact, for example the solar cells produced by First Solar Inc. (USA), use a Cu thickness of 2 nm deposited after CdTe is subjected to a chemical etching (C. R. Corwine et al., Sites, Sol. Energy Mat. & Solar Cells 82 (2004) 481-489).

To avoid any degradation of the device new back-contact materials, namely Sb₂Te₃ and As₂Te₃, are disclosed in WO03/032406 patent application in the name of the same applicant as an alternative to the use of Cu. In particular, Sb₂Te₃ is a material with a low gap (0.3 eV), is of the p-type and has a resistivity close to 10⁻⁴ Ωcm. When deposited at a substrate temperature of 300° C., it forms a close contact with CdTe and can allow efficiencies close to 16% to be reached. This type of contact has proven very stable even with a device illumination of 10-20 suns and temperatures higher than 100° C. However, even if a good quality ohmic contact is formed in this way, under particular conditions of CdTe film growth, the presence of “roll-over” in the J-V characteristic curve has been observed, this being an indication that some rectification, even if not very marked, is present in the back-contact.

It is therefore a general object of the present invention to provide a method to form a ohmic contact for a CdTe thin film which would be completely non-rectifying and ensure the film stability.

A particular object of the present invention, is to provide a method to form an ohmic back-contact of CdS/CdTe thin film solar cells which allows the stability of the cell to be ensured even under high illumination and temperature conditions and therefore to improve, or at least maintain unchanged, the cell efficiency with respect to the prior art.

Another object of the present invention is to provide a method to form a back-contact of thin film solar cells of the above mentioned type wherein, even if Cu is used in the formation of the back-contact, the control of the thickness of the deposited Cu film does not affect the cell stability in the same critical way as occurs in the process according to the prior art.

A further object of the present invention is to provide a method to form a thin film solar cell back-contact of the above mentioned type wherein a treatment of chemical etching of the CdTe film is not necessary before the back-contact is formed.

Still another object of the present invention is to provide a thin film solar cell wherein the back-contact is completely not-rectifying in such a way to ensure an high stability even under high illumination and temperature conditions, and thus improve their efficiency or, at least, maintain it unchanged with respect to the known similar solar cells.

### SUMMARY OF THE INVENTION

These objects are reached with the method to form a non-rectifying back-contact for a CdTe/CdS thin film solar cell and with the solar cell according this method whose essential features are set forth in claims 1 and 14.

According to an aspect of the invention, a method to form a ohmic contact is provided which maintains the photovoltaic device stable in the time without changing the way the CdTe film is treated with respect to the process disclosed in WO 03/032406 and therefore without using any kind of etching of the CdTe film surface.

This new way of contacting the p-type CdTe consists in the sequential deposition of, first, an As₂Te₃ film and then a Cu film by sputtering, but the true contact is provided neither by As₂Te₃ nor by Cu, but through the CuₓTe (with 1≦x≦1.4) compound. It is this compound that ensures both the ohmic behaviour and the time stability of the contact and, therefore, of the solar cells.

In other words, the method according to the invention provides a way to form a non-rectifying ohmic back-contact of the CdTe film consisting in forming a CuₓTe (with 1≦x≦1.4) thereon, which otherwise could not be formable due to the reactivity between Cu and Te. As a matter of fact, if a film containing Cu and Te would be deposited with any method, the final result will be, in any case, the separation of several phases, including the Cu₂Te phase that does not give an ohmic contact and is unstable as it releases Cu atoms. The stable phase between Cu and Te is that with a Cu content comprised between 1 and 1.4, i.e. the phase which, under energetically favorable conditions, is formed by sputtering deposition of a Cu film on a As₂Te₃ film, which in turn is deposited on the surface of a CdTe film as treated in the usual way.

The maximum amount of Cu that it is useful to deposit on the As₂Te₃ layer must ensure at the same time a good non-rectifying contact and a stable system and therefore must allow the formation of CuₓTe (with 1≦x≦1.4) either without leaving free Cu or avoiding the Cu₂Te formation, which would cause the atomic Cu diffusion through the CdTe film and as a consequence the p-n function degradation.

In particular, the CuₓTe (with 1≦x≦1.4) compound can be formed in a native way either directly, by carrying out the Cu film deposition on As₂Te₃ at a temperature comprised between 150° C. and 250° C., or by depositing the As₂Te₃ at low temperature (<100° C.) and then heating the layer assembly at a temperature comprised between 150° and 250° C. A particularly preferred temperature in both cases is at least 180° C. Even if it is not essential to the end of the CuₓTe (with 1≦x≦1.4) compound formation, it can be helpful to maintain the thus formed back-contact at this temperature for at least 1 minute.

In the formation of the back-contact according to the present invention advantage is taken of the particular interaction between these materials during the sputtering deposition of the Cu film on As₂Te₃. In the sputtering technique the atoms reaching the substrate can have an energy of some tens of eV (with thermal evaporation it can be as high as some tenths of eV). At 200° C. the As₂Te₃ film surface starts to become thermally unstable (it starts to reevaporate at 250° C.). On the other side, the Cu atoms have a large energy excess that is partly lost through surface impacts and partly used to break the As₂Te₃ molecule and take the place of the As to form a more stable compound (that is to say with a higher formation energy) at that temperature, i.e. CuₓTe (with 1≦x≦1.4). The stechiometry can be variable (with X variable between 1 and 1.4), as hybridization of the chemical bonds may occur and this may result in increasing formation energies passing from x=1.4 to x=1.

As shown by the X-rays diffractograms, As₂Te₃ blocks Cu, as it reacts with it and if the Cu film is kept at a value not higher than 20 nm, a stable material is formed, i.e. CuₓTe with x comprised between 1 and 1.4, which form a non-rectifying contact with CdTe (see FIGS. 3 and 4).

It has been observed that the same result is not achieved if Sb₂Te₃ is used in the place of As₂Te₃, as Sb₂Te₃ is very stable and does not react with Cu, which may therefore diffuse in the CdTe layer through the Sb₂Te₃ film thus damaging the device.

### BRIEF DESCRIPTION OF THE DRAWINGS

The invention will be now described in further detail with reference to the attached drawings, in which:

FIG. 1 schematically shows the structure of a CdTe/CdS thin film solar cell with the back-contact according to the present invention;

FIG. 2 shows the J-V characteristic curve for two solar cells whose back-contact has been deposited according to the method of the invention, but at two different deposition temperatures (namely: ambient temperature, curve a; 200° C., curve b);

FIG. 3 is the X-ray analysis of an As₂Te₃ film deposited on glass at a substrate of 200° C. with (curve b) and without (curve a) a layer of 20 nm of Cu deposited thereon at the same temperature;

FIG. 4 is the X-ray analysis of an As₂Te₃ film deposited on glass at a substrate temperature of 200° C. with (curve b) and without (curve a) a Cu layer of 50 nm deposited thereon at the same temperature.

### DETAILED DESCRIPTION OF THE INVENTION

The main steps featuring the production of CdTe/CdS tin film solar cells with the new As₂Te₃+Cu back-contact according to the method of the present invention are:

a. Washing of the glass in such a way to remove any trace of organic residues (grease, solvents, etc.) and microparticoles (powder dust with size greater that 1 μm).

b. Deposition of the fore transparent contact by sputtering on the glass said contact comprising two layers: the first layer is ITO (indium-tin oxide) which ensures the condudibility and the second layer is ZnO operates as a buffer layer or as a barrier against the possible diffusion of impurities in the layers which will be deposited in the next steps. Both layers as a whole must ensure a transparency not lower than 85%, in the visible wave length region.

c. Deposition of the CdS film by reactive sputtering (RF-magnetron) under Ar+%5 CHF3 environment, the CdS being a n-type semiconductor providing the first part of the junction.

d. Deposition of the CdTe film by CSS (Close-Spaced Sublimation). The CdTe, being a p-type semiconductor, provides the second part of the junction and ensure the complete absorption of the visible light.

e. Thermal treatment at 400° C. of the whole previously prepared assembly: the CdTe film surface is exposed in a Ar+Freon atmosphere for not more than 5 minutes and then, keeping the temperature at 400° C. for other 5 minutes, vacuum conditions are established thus allowing the volatile compounds, which could have been formed during the first part, to reevaporate from the CdTe film surface.

f. Deposition of the back-contact by sputtering, said back-contact according to the invention comprising two layers: the first one, As₂Te₃, and the second one, Cu:on the back-contact formed in this way a Mo film is then deposited to ensure a proper sheet resistance.

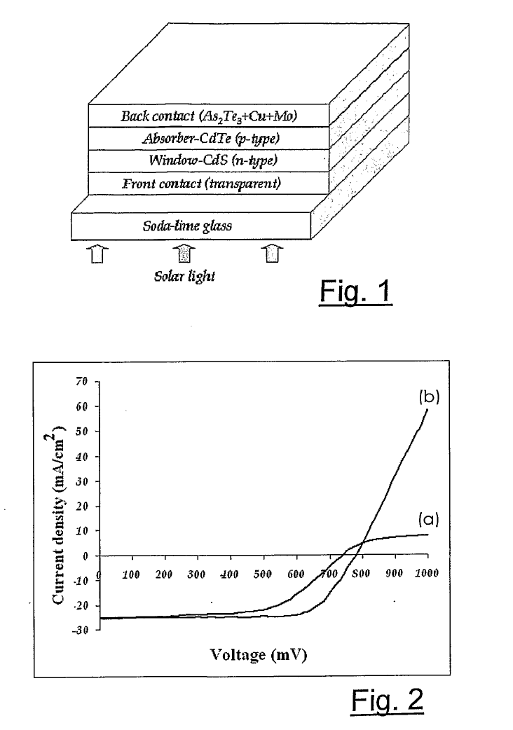

The schematic structure of the solar cell thus produced is shown in FIG. 1.

The As₂Te₃ layer is deposited directly on the CdTe surface, without subjecting the latter to any chemical etching, whereas the Cu layer is deposited at a substrate temperature of around 200° C., preferably 180° C. As₂Te₃ is a p-type semiconductor with prohibited energy band of 0.6 eV and with a resistivity of around 10⁻³Ω cm. The As₂Te₃ thickness can vary between 100 and 300 nm, whereas the Cu thickness can vary between 2 and 20 nm. In the experimental tests both As₂Te₃ and Cu are deposited by sputtering, the first one with a deposition velocity between 10 and 20 Å/sec and the second one with a deposition velocity of 5 Å/sec.

If As₂Te₃ and Cu are both deposited at ambient temperature without any thermal treatment, the result is a rectifying contact as can be seen from FIG. 2, curve a, where a “roll-over” (bending of J-V curve) in the first quadrant of the J-V characteristic curve is visible. If Cu is deposited at a substrate temperature of about 200° C. the roll over disappears (curve b of FIG. 2) and the fill factor of the device is very higher in this case (0.7 instead of 0.57 in the first case).

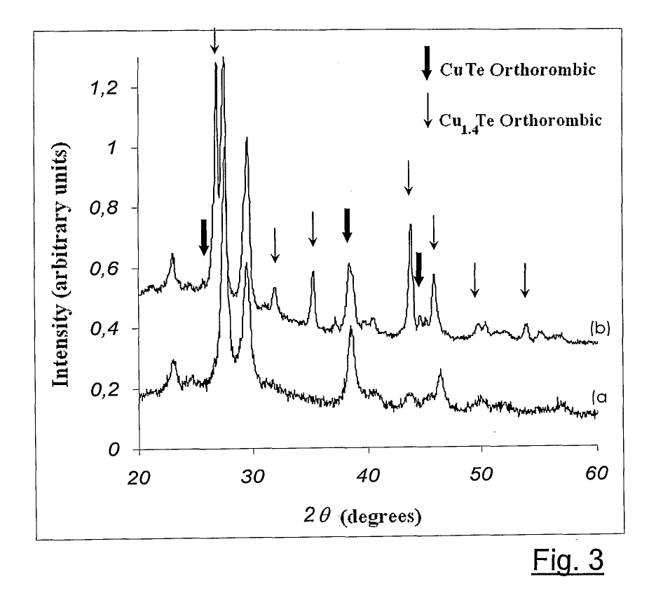

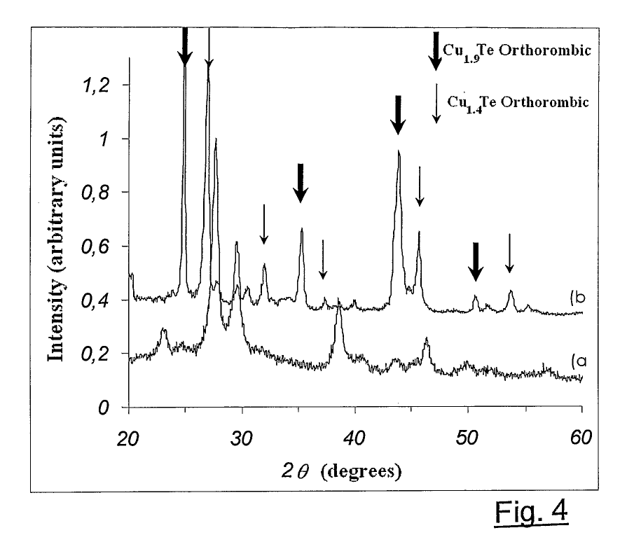

To understand the behaviour of this double layer of As₂Te₃+Cu, some samples were prepared by depositing As₂Te₃+Cu directly on glass and Cu was deposited at a substrate temperature of about 200° C. Moreover, some samples were prepared by depositing a Cu thickness up to 20 nm on As₂Te₃, whereas others were prepared depositing a Cu layer of about 50 nm. These samples were x-rays analysed and compared with samples containing As₂Te₃ only. It was observed that the samples containing Cu with a layer thickness not higher than 20 nm exhibited several CuₓTe phases with 1≦X≦1.4 (FIG. 3, curves a and b), whereas the samples containing Cu with a layer thickness of 50 nm exhibited even the Cu₂Te phase (FIG. 4, curves a and b). The result of the above tests is that a layer of Cu up a 20 nm thickness can be deposited forming phases of CuₓTe (with 1≦X≦1.4) which form a stable non-rectifying contact with CdTe. This is also confirmed by the J-V characteristic curve shown in FIG. 2, curve b, of a CdTe/CdS cell in which the back-contact has been made by depositing in sequence, at a substrate temperature of about 200° C., 200 nm of As₂Te₃ and 20 nm of Cu, without carrying out any etching on the CdTe surface. The fill factor of this cell is ˜0.7.

From these data it can be concluded that As₂Te₃ behaves as a barrier for Cu and that, when Cu is deposited at a lower temperature and then is brought at about 200° C. after the deposition, a solid state reaction between As₂Te₃ and Cu takes place in which Cu displaces As forming the CuₓTe phase.

The way of forming a non-rectifying contact on p-type CdTe looks like to that commonly used in which a Te-rich surface is first created by a chemical etching of CdTe and then Cu is deposited to form CuₓTe. However, the substantial difference consists in that, in the method of the invention, any CdTe etching is not carried out and that an up to ten times higher amount of Cu can be used. This makes less critical the risk of formation of the rectifying contact thereby allowing a greater stability of the contact.

To the aim of assessing the performances and the photovoltaic parameters, several samples of solar cells were prepared following the method of the invention by depositing in sequence by sputtering different thicknesses of As₂Te₃ and Cu as set forth in the following table:

| | As₂Te₃ | | substrate |
|---|---|---|---|
| sample | nm | Cu nm | temperature, ° C. |
| 1 | 100 | 20 | 200 |
| 2 | 300 | 5 | 200 |
| 3 | 200 | 10 | <100 |

In the case of the sample 3 the system formed by all the deposited layer was brought to a substrate temperature comprised between 180° C. and 250° C. in a Ar atmosphere at a pressure comprised between 100 mbar and 1 atm. In all the samples the contact was completed by depositing a Mo layer of 150 nm on the surface of the As₂Te₃₊Cu film.

Physically relevant differences of the contact behaviour as a function of the deposition velocity were not observed (both for As₂Te₃ and Cu) when the velocity was comprised between few Å/sec up to 50 Å/sec and the substrate temperature varied from 150° C. to 250° C.

In all these cases the back-contact has proven to be a good contact for the CdTe/Cds thin solar film solar cell as shown by the J-V characteristic (FIG. 2, curve b). In fact, in the positive part of the characteristic (1° quadrant), no bending is displayed, which demonstrates that the contact is non-rectifying and from the curve inclination and fill factor it can be deduced that there is not any series resistance effect. Therefore, the contact is non-rectifying and is of low resistance. Stability tests were carried out by subjecting the device, in open circuit condition, to “light soaking”, i.e. an exposition to an intense illumination, up to 10 suns and temperature up to 100° C. for 8 hours without noting any significant degradation of the photovoltaic parameters of the device.

Even if the preferred deposition technique for both layers of As₂Te₃ and Cu is by sputtering, they may be also deposited by thermal evaporation, by electronic gun evaporation or electrodeposition.

Variations and/or modifications may be brought to the method for forming a non-rectifying ohmic contact for CdTe/Cds thin films and to the thin film solar cell according to the present invention without departing from the scope of the invention as seth forth in the following claims.

What is claimed is:

1. A method of forming a non-rectifying ohmic contact on a p-type semiconductor CdTe thin film, the method comprising the steps of:
a) depositing a layer of As₂Te₃ on the CdTe layer at a substrate temperature generally within a range of ambient temperature and 200° C.;
b) depositing a layer of Cu on the As₂Te₃ layer; and
c) bringing at least the deposited Cu layer to a temperature generally within a range of 150° C. and 250° C.

2. The method set forth in claim 1, wherein the thickness of the deposited Cu layer is not greater than about 20 nm.

3. The method set forth in claim 1, wherein deposition of the Cu layer occurs at a temperature generally within a range of 150° C. and 250° C.

4. The method set forth in claim 1, wherein deposition of the Cu layer occurs at a temperature lower than about 100° C. and then the layer assembly is brought to a temperature generally within a range of 150° C. and 250° C.

5. The method set forth in claim 4, wherein heating at a temperature generally within a range of 150° C. and 250° C. occurs in an Ar atmosphere and at a pressure generally within a range of 100 mbar and 1 atm.

6. The method set forth in claim 4, wherein the layer assembly is maintained at a temperature generally within a range of 150° C. and 250° C. for at least one minute.

7. The method set forth in claim 1, wherein the thickness of the deposited As₂Te₃ layer is generally within a range of 100 nm and 300 nm.

8. The method set forth in claim 1, wherein the contact is the back-contact of a CdTe/CdS thin file solar cell.

9. The method set forth in claim 1, wherein the As₂Te₃ layer is deposited on a CdTe layer that is not subjected to chemical etching treatment.

10. The method set forth in claim 1, wherein a layer of Mo is deposited on the Cu layer.

11. The method set forth in claim 1, wherein the layers of As₂Te₃, Cu and Mo are deposited by sputtering.

12. The method set forth in claim 1, wherein the layers of As₂Te₃, Cu and Mo are deposited by thermal evaporation, electronic gun evaporation, electrodeposition.

13. The method set forth in claim 1, wherein the ohmic contact is formed by CuₓTe where 1≦x≦1.4.

14. A CdTe/CdS thin film solar cell, which comprises a multi-layer structure including a transparent substrate, a conductive oxide layer deposited on the substrate, an n-type CdS semiconductor layer, a p-type CdTe semiconductor layer, and at least a Cu-containing back-contact, the structure further comprising an As₂Te₃ layer deposited on the CdTe semiconductor layer and a layer of CuₓTe where 1≦x≦1.4 formed in the As₂Te₃ layer.

15. The solar cell set forth in claim 14, wherein the thickness of the deposited Cu layer is not greater than about 20 nm.

16. The solar cell set forth in claim 14, wherein the thickness of the deposited As₂Te₃ layer is generally within a range of 100 nm and 300 nm.
